(19) United States
(12) Patent Application Publication
(10) Pub. No.: US 2025/0366053 A1
(43) Pub. Date: Nov. 27, 2025

(54) NANOSHEET GATE METAL SCHEME COMPATIBLE WITH AGGRESSIVE GATE WIDTH SCALING

(71) Applicant: Taiwan Semiconductor Manufacturing Co., Ltd., Hsinchu (TW)

(72) Inventors: Chung-Wei HSU, Hsinchu (TW); Lung-Kun CHU, Hsinchu (TW); Jia-Ni YU, Hsinchu (TW); Chun-Fu LU, Hsinchu (TW); Shih-Hao LAI, Hsinchu (TW); Kuo-Cheng CHIANG, Hsinchu (TW); Chih-Hao WANG, Hsinchu (TW)

(73) Assignee: Taiwan Semiconductor Manufacturing Co., Ltd., Hsinchu (TW)

(21) Appl. No.: 19/292,658

(22) Filed: Aug. 6, 2025

Related U.S. Application Data
(63) Continuation of application No. 18/404,533, filed on Jan. 4, 2024.
(60) Provisional application No. 63/578,577, filed on Aug. 24, 2023.

(51) Int. Cl. H10D 30/67; H10D 30/01; H10D 30/43; H10D 62/10; H10D 84/01; H10D 84/03; H10D 84/85

(52) U.S. Cl. CPC H10D 30/6735; H10D 30/014; H10D 30/43; H10D 62/121; H10D 84/0167; H10D 84/0172; H10D 84/038; H10D 84/85

(57) ABSTRACT

An integrated circuit includes a transistor having a plurality of stacked channels each extending between the source/drain regions of the transistor. The transistor also includes a hard mask nanostructure above the highest channel and extending between the source/drain regions of the transistor. A gate dielectric and gate metals wrap around the channels and the hard mask nanostructure.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-2K are cross-sectional views of an integrated circuit at various stages of processing, in accordance with some embodiments.

FIG. 3 is a cross-sectional view of an integrated circuit, in accordance with some embodiments.

FIG. 4 is a cross-sectional view of an integrated circuit, in accordance with some embodiments.

FIG. 5 is a cross-sectional view of an integrated circuit, in accordance with some embodiments.

FIG. 6 is a flow diagram of a method for forming an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets). Gate-drain capacitance (“Cgd”) is increased due to larger metal gate endcap and increased source/drain epitaxy size.

Embodiments of the disclosure nanostructure transistors each includes a plurality of stacked channels. A hard mask nanostructure is positioned above the highest channel of each transistor. The gate metals of the transistors wrap around the channels and the hard mask nanostructures. The presence of the hard mask nanostructure helps prevent loss of the high-K gate dielectric from a top surface of the highest channel of each transistor. Furthermore, the presence of the hard mask nanostructure helps reduce the constraints of gate width spacing. The result is that further scaling of critical poly-gate pitch and cell height can be achieved. The result is that scaling of transistors can be improved while electrical characteristics of transistors are protected and maintained. This results in improved wafer yields and better functioning electronic devices.

The nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistor structure.

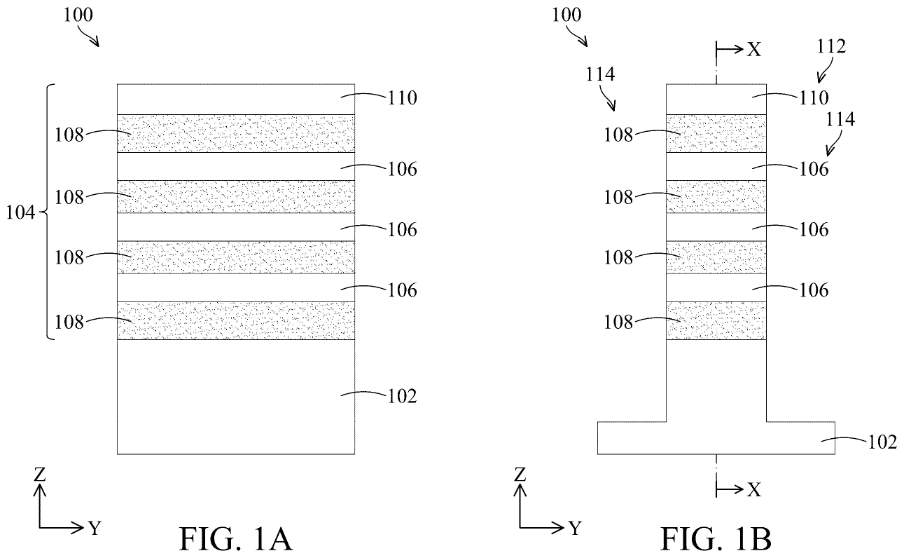

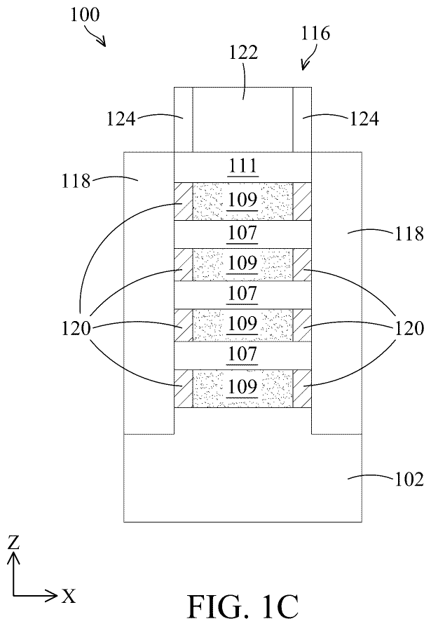

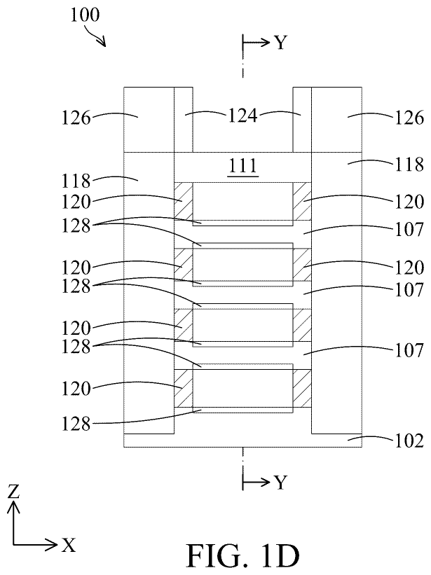

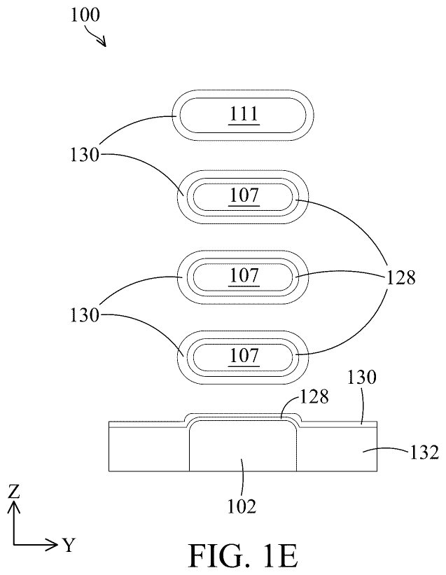

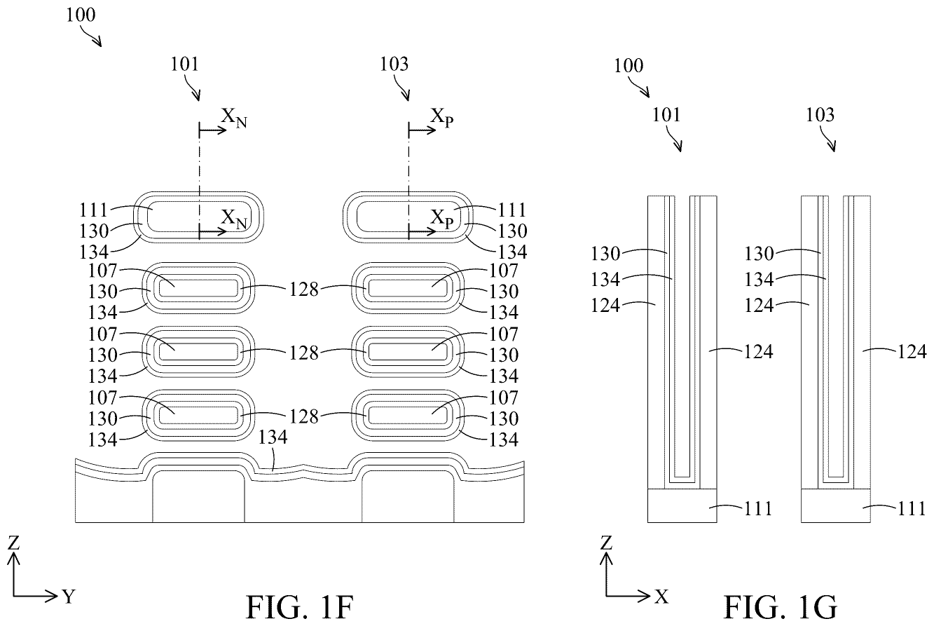

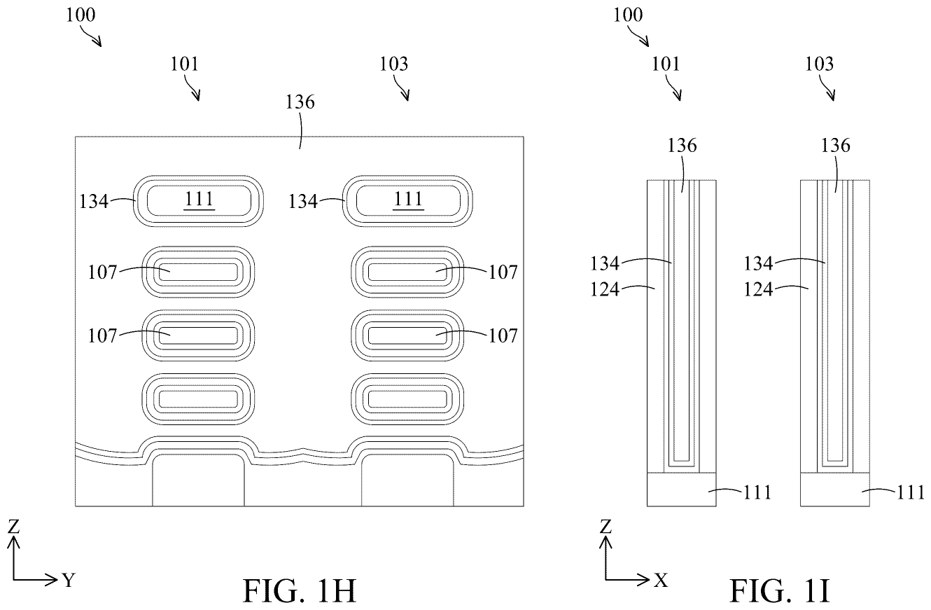

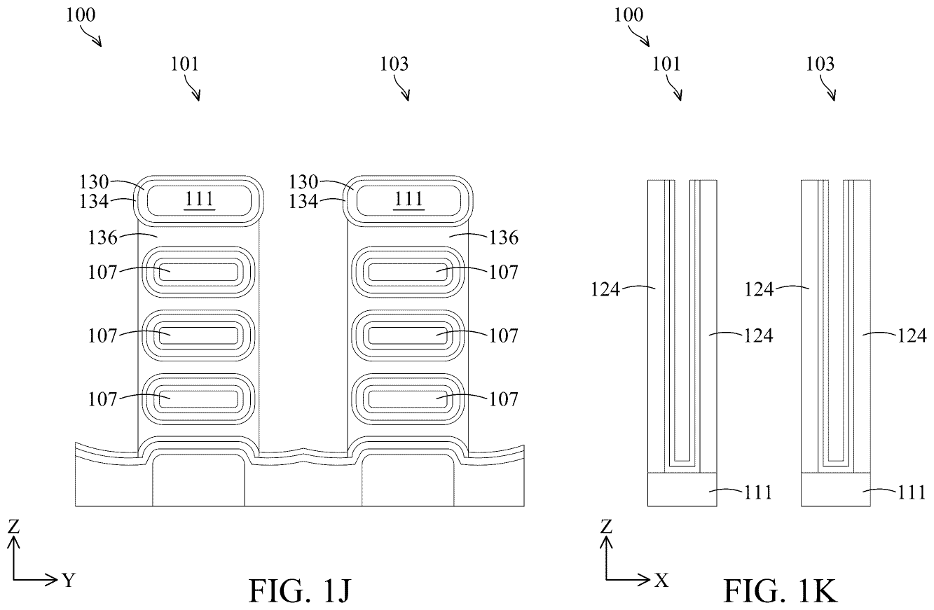

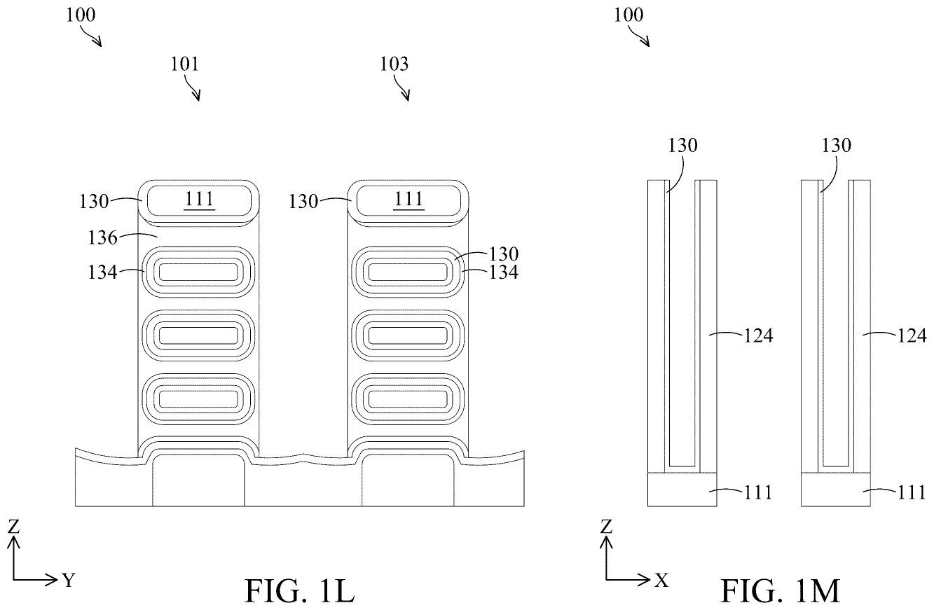

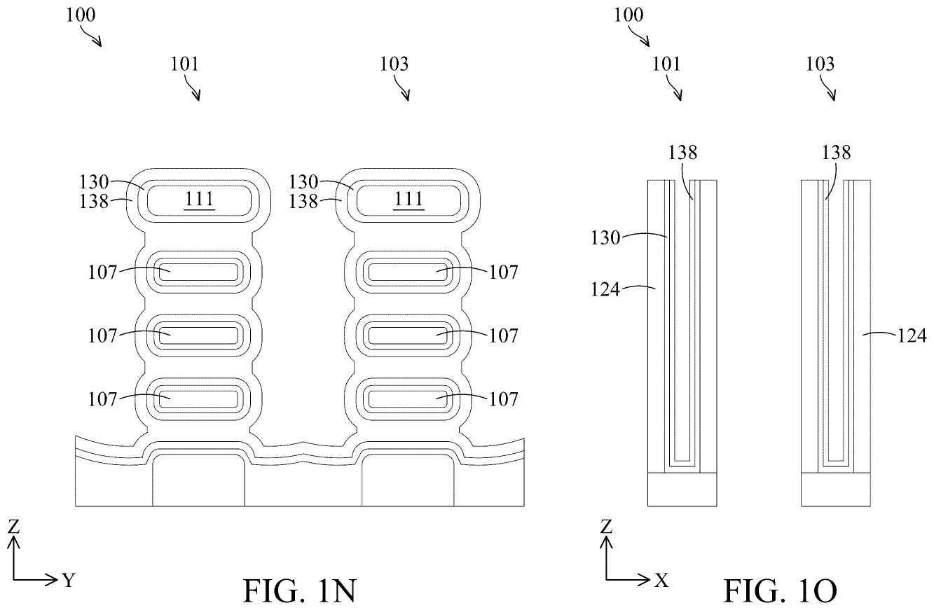

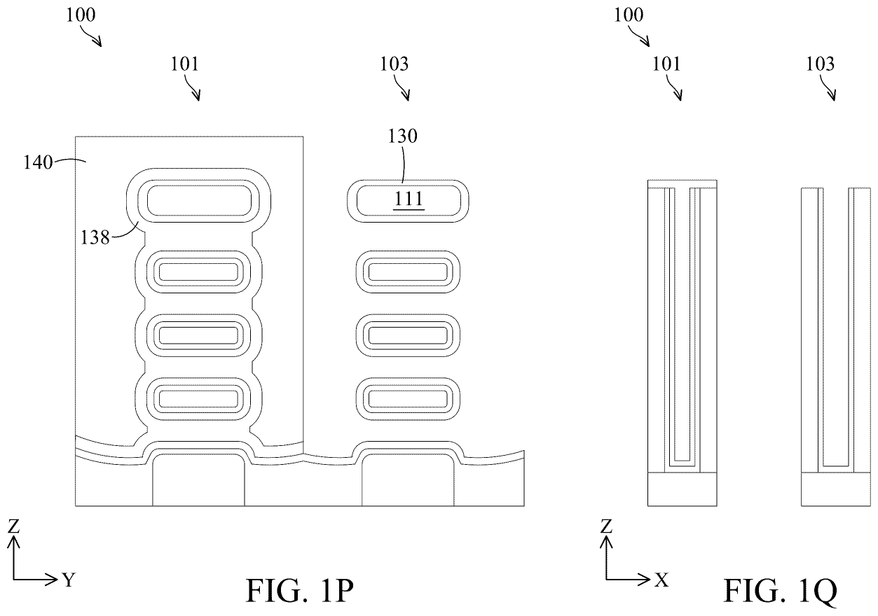

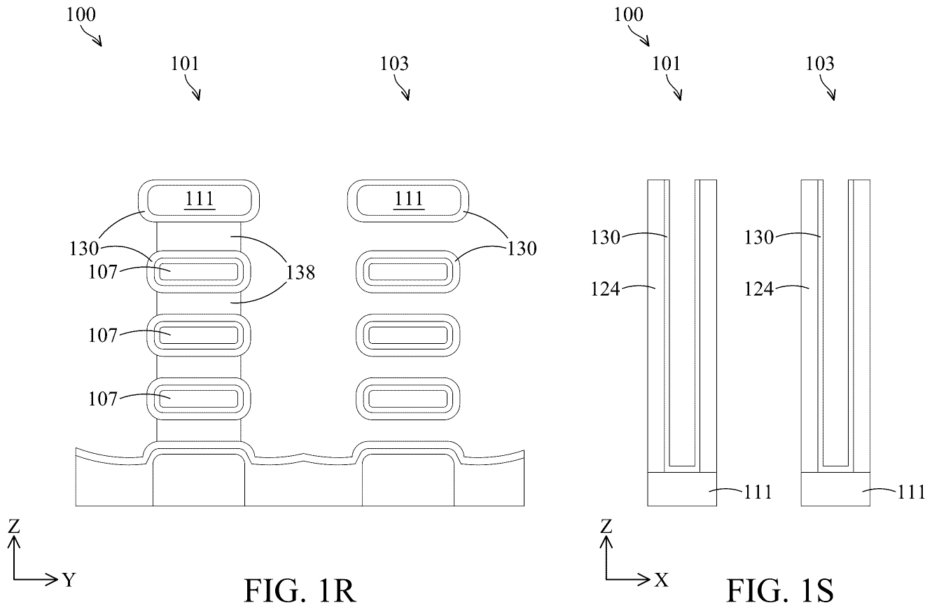

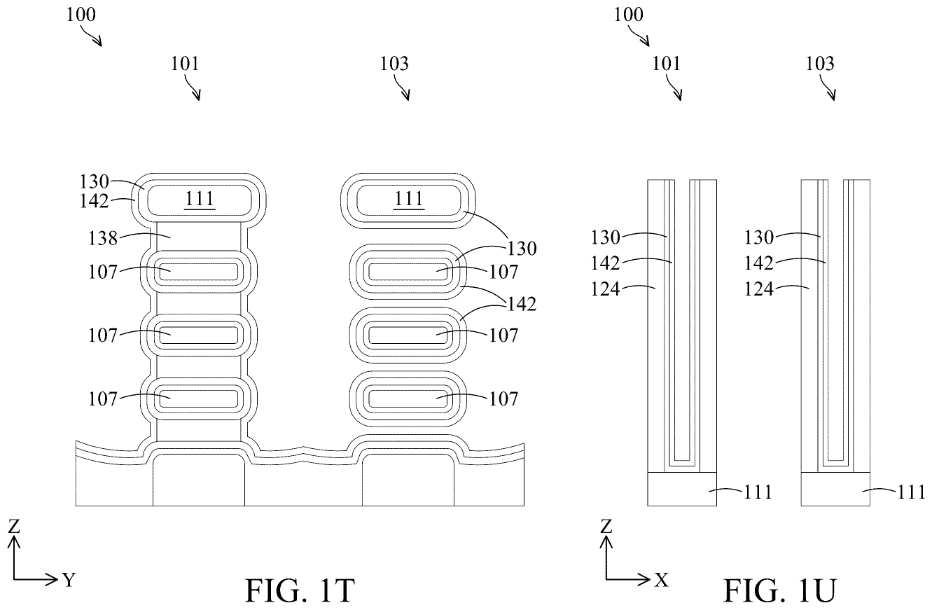

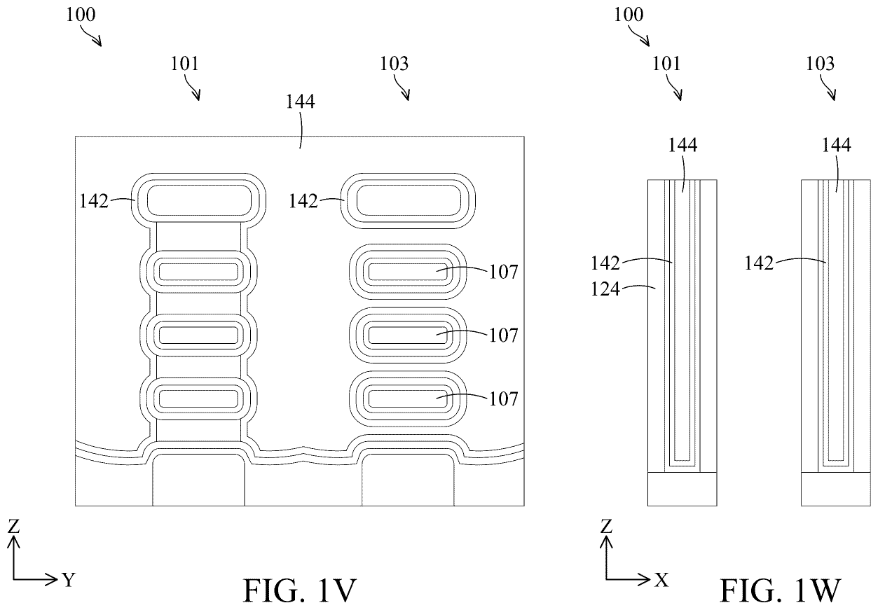

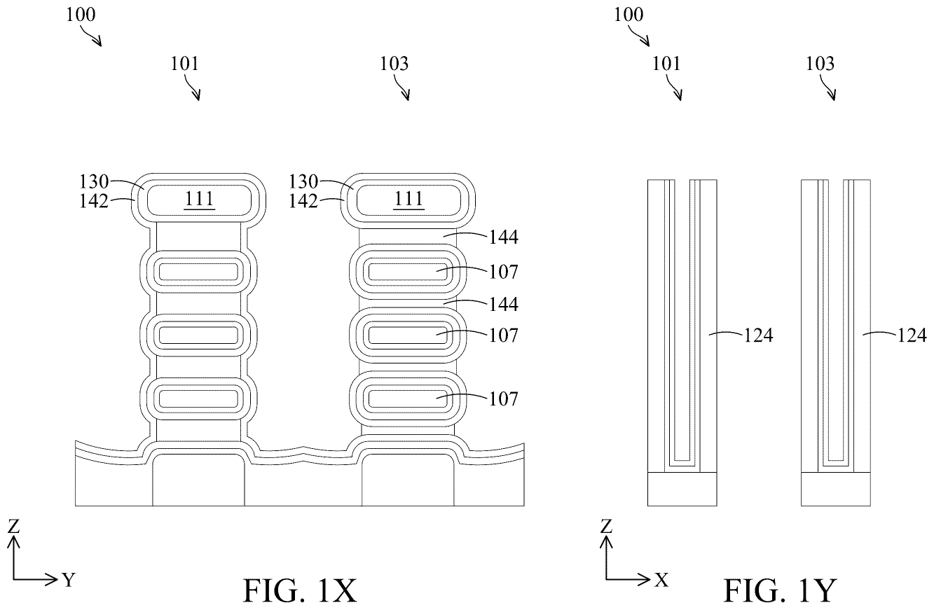

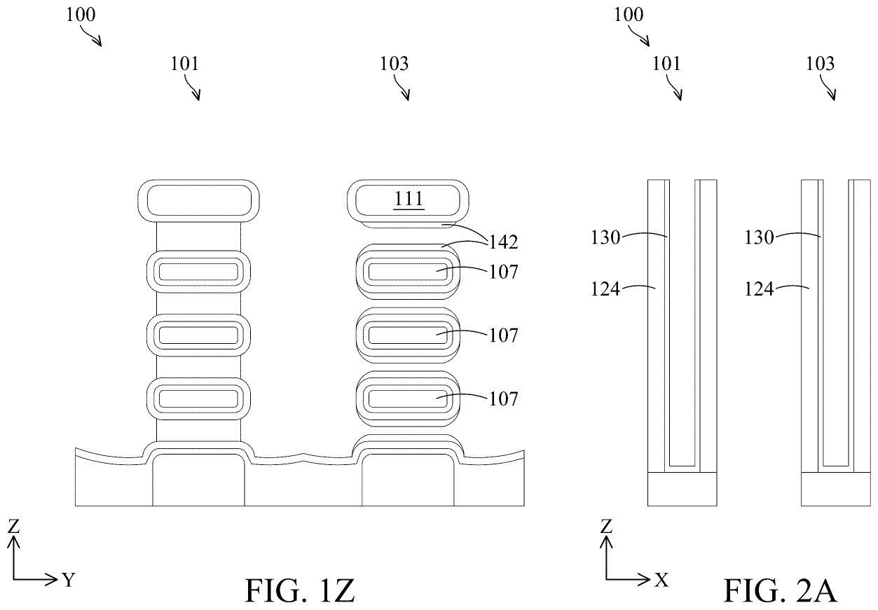

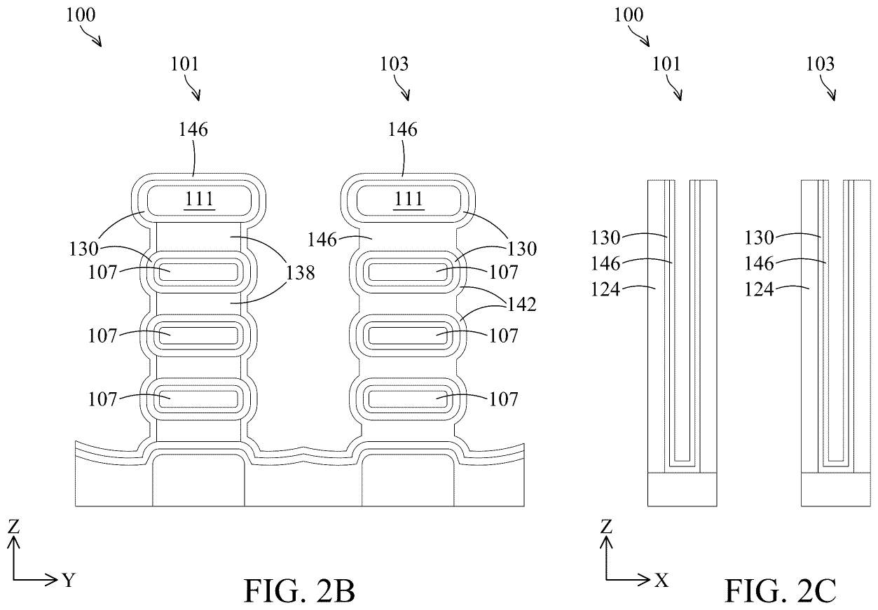

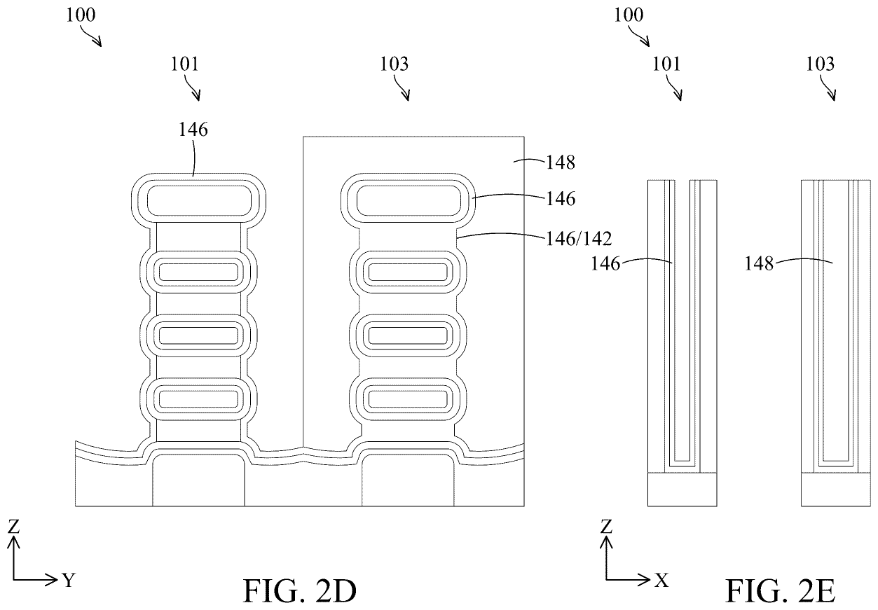

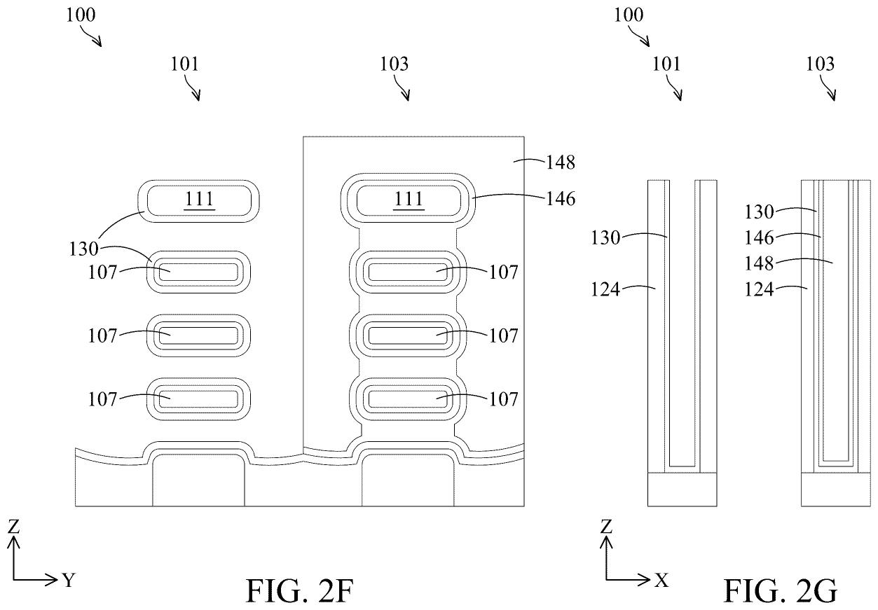

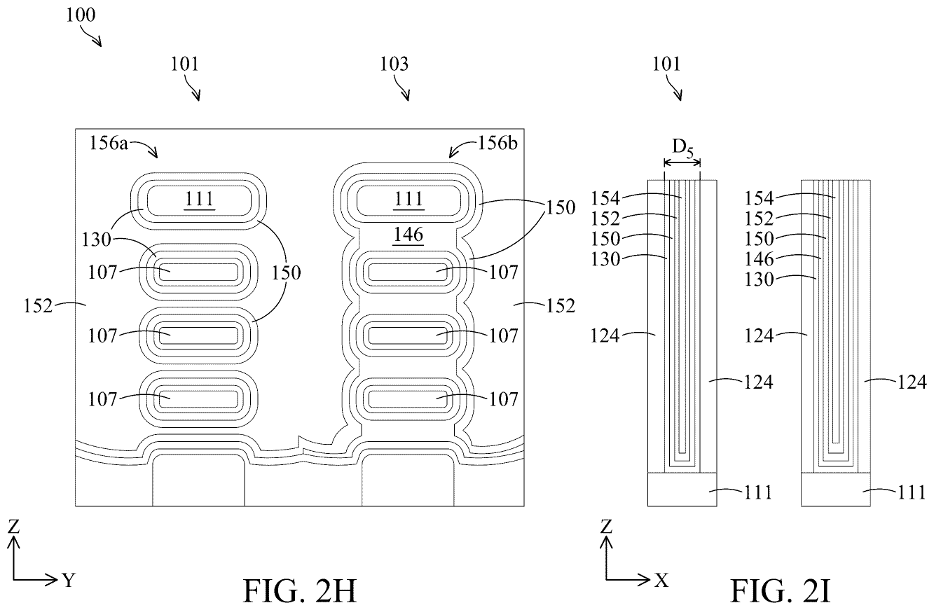

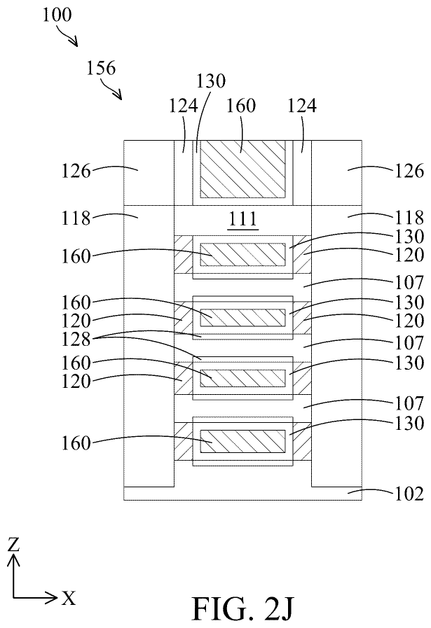

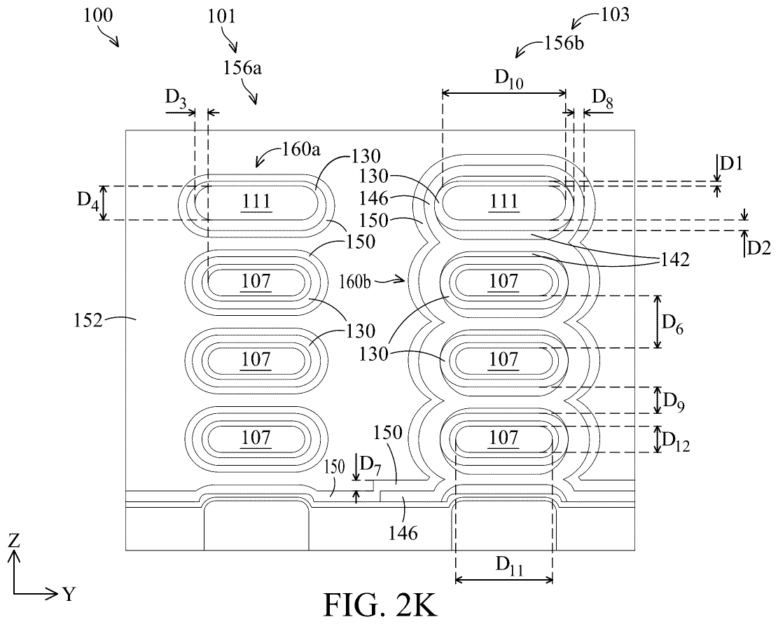

FIGS. 1A-2K are cross-sectional views of an integrated circuit 100 at various stages of processing, in accordance with some embodiments. The fabrication process results in a plurality of semiconductor nanostructure transistors, as will be described in further detail below.

FIG. 1A is a cross-sectional view of the integrated circuit 100 at an intermediate state of processing, in accordance with some embodiments. The integrated circuit 100 includes a substrate 102. The substrate 102 may be a semiconductor substrate, such as a bulk semiconductor, or the like, which may be doped (e.g., with a p-type or an n-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a stack 104. The stack 104 includes a plurality of semiconductor layers 106 and sacrificial semiconductor layers 108 alternating with each other. As will be set forth in further detail below, the semiconductor layers 106 will be patterned to form semiconductor nanostructures of a plurality of transistors. As set forth in more detail below, the sacrificial semiconductor layers 108 will eventually be entirely removed and are utilized to enable forming gate metals and other structures around the semiconductor nanostructures. The stack also includes a hard mask layer 110 on top of the highest sacrificial semiconductor layer 108.

In some embodiments, the semiconductor layers 106 may be formed of a first semiconductor material suitable for n-type semiconductor nanostructure transistors, such as silicon, silicon carbide, or the like, and the sacrificial semiconductor layers 108 may be formed of a second semiconductor material suitable for p-type semiconductor nanostructure transistors, such as silicon germanium or the like. Each of the layers of the stack 104 may be epitaxially grown using a process such as chemical vapor deposition (CVD), atomic layer deposition (ALD), vapor phase epitaxy (VPE), molecular beam epitaxy (MBE), or the like. The hard mask layer 110 can include a dielectric material such as SiN, SiCN, SiC, SiOCN, or other suitable dielectric materials.

Three semiconductor layers 106 and four sacrificial semiconductor layers 108 are illustrated. In some embodiments, the multi-layer stack 104 may include more or fewer of the semiconductor layers 106 and the sacrificial semiconductor layers 108. Although the stack 104 is illustrated as including a sacrificial semiconductor layer 108 as the bottommost layer of the multi-layer stack 104, in some embodiments, the bottommost layer of the multi-layer stack 104 may be a semiconductor layer 106.

Due to high etch selectivity between the materials of the semiconductor layers 106 and the sacrificial semiconductor layers 108, the sacrificial semiconductor layers 108 of the second semiconductor material may be removed without significantly removing the semiconductor layers 106 of the first semiconductor material, thereby allowing the semiconductor layers 106 to be released to form channel regions of semiconductor nanostructure transistors.

In FIG. 1B, the stack 104 has been patterned to form a plurality of fins 112. FIG. 1B only illustrates a single fin 112. The fins 112 extend in the X direction, i.e., into and out of the drawing sheet of FIG. 1B. The fins 112 are separated from each other by trenches 114. Said another way, the fins 112 are defined by forming trenches in the stack 104. The fins 112 may be defined by an etching process. In particular, an etching process has been performed in conjunction with a photolithography mask to define the fins 112 from the initial single stack. The etching process can include an anisotropic etching process that etches in the downward direction. The etching process defines fins 112 by forming trenches 114 through the sacrificial semiconductor layers 108, the semiconductor layers 106, and the substrate 102.

After formation of the trenches 114, trench isolation regions (not shown), which may be shallow trench isolation (STI) regions, may be formed in the trenches 114. The trench isolation regions may be formed by depositing a dielectric material. In some embodiments, the dielectric material is formed over the substrate 102, the fins 112, and between adjacent fins 112. The dielectric material may be an oxide, such as silicon oxide, a nitride, the like, or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 102 and the fins 112.

An etch-back process has been performed to reduce the top surface of the trench isolation regions to a level below the lowest sacrificial semiconductor layer 108. The etching process can include a wet etch, dry etch, a timed etch, or other types of etching processes that can recess the height of the shallow trench isolation regions. The result is that the sidewalls of the semiconductor layers 106 and sacrificial semiconductor layers 108 of the fins 112 are exposed.

Though not shown in FIG. 1B, appropriate wells (not separately illustrated) may also be formed in the fins 112 and/or the trench isolation regions. Using masks, an n-type impurity implant may be performed in p-type regions of the substrate 102, and a p-type impurity implant may be performed in n-type regions of the substrate 102. Example n-type impurities may include phosphorus, arsenic, antimony, or the like. Example p-type impurities may include boron, boron fluoride, indium, or the like. An annealing may be performed after the implants to repair implant damage and to activate the p-type and/or n-type impurities. In some embodiments, in situ doping during epitaxial growth of the stack 104 may obviate separate implantations, although in situ and implantation doping may be used together.

FIG. 1C is a cross-sectional view of the integrated circuit 100 after several processing steps have been performed since the stage of processing shown in FIG. 1B, in accordance with some embodiments. Furthermore, the cross-sectional view of FIG. 1C is an X-view taken along a line corresponding to cut lines X in FIG. 1B, though after various processing steps.

In FIG. 1C, sacrificial gate structures 116 have been formed over the fins 112 and over the trench isolation regions (not shown). Due to the limited nature of the view of FIG. 1B in the X-direction, only a single sacrificial gate structure 116 is shown in FIG. 1C. In practice, many other sacrificial gate structures 116 may be formed substantially parallel to and concurrently with the sacrificial gate structure 116 shown in FIG. 1C.

The sacrificial gate structure 116 includes a sacrificial gate layer 122. The sacrificial gate layer 122 can include materials that have a high etch selectivity with respect to the trench isolation regions. The sacrificial gate layer 122 may be a conductive, semiconductive, or non-conductive material and may be or include amorphous silicon, polycrystalline-silicon (polysilicon), poly-crystalline silicon-germanium (poly-SiGe), metallic nitrides, metallic silicides, metallic oxides, and metals. The sacrificial gate layer 122 may be deposited by physical vapor deposition (PVD), CVD, sputter deposition, or other techniques for depositing the selected material. Although the sacrificial gate structure 116 illustrates a single layer in FIG. 1C, in practice, the sacrificial gate structure 116 may include a plurality of dielectric layers.

The sacrificial gate structure 116 is bounded by the gate spacer layers 124. As will be set forth in more detail below, eventually the sacrificial gate layer 122 will be removed from between the gate spacer layers 124 for gate metals. The gate spacer layers 124 can be formed by PVD, CVD, ALD, or other suitable deposition processes. Following formation of the gate spacer layer 124, horizontal portions (e.g., in the X-Y plane) of the gate spacer layer 124 may be removed, thereby exposing upper surfaces of the fins 112 and the trench isolation regions. The gate spacer layers 124 can include one or more of SiO, SiN, SiON, SiCN, SiOCN, SiOC, or other suitable dielectric materials.

In FIG. 1C, after formation of the gate spacer layers 124, one or more etching operations have been performed to recess the fins 112 exposed through the gate spacer layer 124, in accordance with some embodiments. This etching process results in the formation of source/drain trenches in the fins 112. In FIG. 1C, the trenches have been filled with source/drain regions 118, as will be described in more detail below.

The etching process that forms the source/drain trenches in the fin 112 also results in the singulation of individual stacks of nanostructures. Each stack includes a plurality of channels 107, a plurality of sacrificial semiconductor nanostructures 109 and a hard mask nanostructure 111 on top of the highest sacrificial semiconductor nanostructure 109. The channels 107 are formed from the semiconductor layers 106. The sacrificial semiconductor nanostructures 109 are formed from the sacrificial semiconductor layers 108. The hard mask nanostructure 111 is formed from the hard mask layer 110. In the example of FIG. 1C, each stack includes three stacked channels 107 and four sacrificial semiconductor nanostructures 109. The stacked channels 107 of each stack will eventually correspond to channel regions of a respective transistor. Accordingly, an individual transistor will be formed in conjunction with each stack, therefore only a single stack is shown in FIG. 1C. The sacrificial semiconductor nanostructures 109 are one example of sacrificial nanostructures. In some cases, the sacrificial semiconductor nanostructures may be replaced by sacrificial nanostructures of dielectric material.

The channels 107 are semiconductor nanostructures. The semiconductor nanostructures can include semiconductor nanosheets, semiconductor nanowires, or other types of semiconductor nanostructures. The hard mask nanostructure 111 is similar in shape and orientation to the semiconductor nanostructures of the channels 107. However, the hard mask nanostructure 111 differs from the semiconductor nanostructures of the channels 107 in that the hard mask nanostructure is a dielectric material that does not carry a current during operation of the transistors. The presence of the hard mask nanostructure 111 results in flexibility in scaling gate widths and interior channel spacings.

After formation of the source/drain trenches and prior to formation of the source/drain regions 118, the lateral ends of the channels 107, the sacrificial semiconductor nanostructures 109, and the hard mask nanostructure 111 are exposed. A selective etching process is performed to recess exposed end portions of the sacrificial semiconductor nanostructures 109 without substantially etching the channels 107 or the hard mask nanostructure 111, in accordance with some embodiments. The material of the sacrificial semiconductor nanostructures 109 is selectively etchable with respect to the material of the semiconductor channels 107. Accordingly, the sacrificial semiconductor nanostructures 109 can be recessed without substantially etching the channels 107. The etching process results in the recesses formed in the sacrificial semiconductor nanostructures 109.

In FIG. 1C, inner spacers 120 has been conformally formed in the recesses of the sacrificial semiconductor layer 109 prior to formation of the source/drain regions 118. Initially, a dielectric material of the inner spacers 120 may be conformally deposited. The inner spacers 120 can include a dielectric material such as SiCN, SiOCN, or the like, formed by a suitable deposition method such as physical vapor deposition (PVD), CVD, ALD, or the like. An etching process may then be performed to remove the dielectric material from all locations outside of the recesses. The result is the inner spacers 120 shown in FIG. 1C. As will be set forth in more detail below, the presence of the inner spacers helps to electrically isolate subsequently deposited gate metals from the source/drain regions 118.

After formation of the inner spacers 120, the source/drain regions 118 have been formed in the source/drain trenches, in accordance with some embodiments. In the illustrated embodiment, the source/drain regions 118 are epitaxially grown from epitaxial material(s). The source/drain regions 118 are grown on exposed portions of the channels 107 and the substrate 102 in the trenches.

For each stack, there are two source/drain regions 118. Each source/drain region 118 is in direct contact with the side surfaces of the channels 107 of the corresponding stack. The channels 107 of each stack extend in the X-direction between two source/drain regions 118.

The source/drain regions 118 may include any acceptable material, such as appropriate for n-type or p-type devices. For n-type devices, the source/drain regions 118 include materials exerting a tensile strain in the channel regions, such as Si, SiC, SiCP, SiP, or the like, in some embodiments. When p-type devices are formed, the source/drain regions 118 include materials exerting a compressive strain in the channel regions, such as SiGe, SiGeB, Ge, GeSn, or the like, in accordance with certain embodiments. The source/drain regions 118 may have surfaces raised from respective surfaces of the fins and may have facets. Neighboring source/drain regions 118 may merge in some embodiments to form a singular source/drain region 118 over two neighboring fins of the fins 112.

The source/drain regions 118 may be implanted with dopants followed by an annealing process. The source/drain regions 118 may have an impurity concentration of between about 10¹⁹ cm⁻³ and about 10²¹ cm⁻³. N-type and/or p-type impurities for source/drain regions 118 may be any of the impurities previously discussed. In some embodiments, the source/drain regions 118 are in situ doped during growth.

In FIG. 1D, an interlevel dielectric layer 126 has been formed. Though not shown, a contact etch stop layer (CESL) may be formed prior to formation of the interlevel dielectric layer 126. The CESL layer can include a thin dielectric layer that can be conformally deposited on exposed surfaces of the source/drain regions 118 and the trench isolation regions. The CESL layer can include SiN, SiC, SiOC, SiOCN, SiON, or other suitable dielectric materials. The CESL can be deposited by CVD, ALD, PVD, or other suitable deposition processes.

The dielectric layer 126 covers the CESL. The dielectric layer 126 can include SiO, SiON, SiN, SiC, SiOC, SiOCN, or other suitable dielectric materials. The dielectric layer 126 can be deposited by CVD, ALD, PVD, or other suitable deposition processes.

In FIG. 1D, the sacrificial gate structure 116 has been removed. In particular, the sacrificial gate layer 122 has been removed. The result is that there is a gap between the gate spacers 124. The sacrificial gate layer 122 can be removed by an etching process that selectively etches the sacrificial gate layer 122 with respect to other exposed materials.

After removal of the sacrificial gate layer 122, an etching process has been performed to entirely remove the sacrificial semiconductor nanostructures 109 from each stack. This corresponds to releasing the channels 107. Because the sacrificial semiconductor nanostructures 109 are selectively etchable with respect to the channels 107, the channels 107 are not substantially etched during removal of the sacrificial semiconductor nanostructures 109. The result is that there is a gap between each of the channels 107 in each stack.

The sacrificial semiconductor nanostructures 109 can be removed by a selective etching process using an etchant that is selective to the material of the sacrificial semiconductor nanostructures 109, such that the sacrificial semiconductor nanostructures 109 are removed without substantially etching the channels 107. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like. In some embodiments, the sacrificial semiconductor nanostructures 109 are removed and the channels 107 are patterned to form channel regions of both PFETs and NFETs.

In FIG. 1D, an interfacial gate dielectric layer 128 has been formed in contact with the exposed surfaces of the channels 107 and the substrate 102. The interfacial gate dielectric layer 128 can correspond to a native oxide that consumes a surface portion of exposed semiconductor materials. The interfacial gate dielectric layer 128 surrounds the channels 107. The interfacial gate dielectric layer 128 can include a dielectric material such as silicon oxide, silicon nitride, or other suitable dielectric materials. The interfacial gate dielectric layer 128 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 128 can be formed by a thermal oxidation process, a chemical vapor deposition (CVD) process, or an atomic layer deposition (ALD) process. The interfacial gate dielectric layer 128 can have a thickness between 0.5 nm and 2 nm. Other materials, deposition processes, and thicknesses can be utilized for the interfacial gate dielectric layer 128 without departing from the scope of the present disclosure.

FIG. 1E is a cross-sectional view of the integrated circuit 100, in accordance with some embodiments. The view of FIG. 1E corresponds to a Y-view taken along the location of the cut lines Y of FIG. 1D.

In FIG. 1E, a high-K gate dielectric layer 130 has been deposited. The high-K gate dielectric layer 130 is deposited in a conformal deposition process. The conformal deposition process deposits the high-K gate dielectric layer 130 on the interfacial gate dielectric layer 128 and on sidewalls of the gate spacer layers 124. The high-K gate dielectric layer 130 surrounds the channels 107. The high-K gate dielectric layer 130 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K gate dielectric layer 130 may be formed by CVD, ALD, or any suitable method. Other thicknesses, deposition processes, and materials can be utilized for the high-K gate dielectric layer 130 without departing from the scope of the present disclosure.

The high-K gate dielectric layer 130 wraps around each of the channels 107 and the separated from each channel 107 by the interfacial gate dielectric layer 128. The high-K gate dielectric layer 130 wraps around and is in direct contact with the hard mask nanostructure 111. The high-K gate dielectric layer 130 is on a top surface of the trench isolation regions 132. The trench isolation regions 132 can be formed as described previously.

As will be described in more detail below, the total width of the hard mask nanostructure 111 in the Y direction is somewhat greater than the total width of the channels 107 in the Y direction. The hard mask nanostructure 111 also has a greater thickness in the Z direction than do the channels 107. This difference in thickness and width can be a result of the etching process that releases the channels 107 by removing the sacrificial semiconductor nanostructures 109. While the etching process selectively etches the material of the sacrificial semiconductor nanostructures 109 with respect to the material of the channels 107, the channels 107 are nevertheless etched to a relatively small extent. The hard mask nanostructure 111 is substantially unetched. The result is that the hard mask nanostructure 111 have slightly larger dimensions than the channels 107.

In subsequent figures, many figures illustrate two separate regions of the integrated circuit 100, in accordance with some embodiments. In particular, subsequent figures may illustrate a first region 101 and a second region 103. The first region 101 may correspond to a region of the integrated circuit 100 at which N-type transistors are to be formed. The second region 103 may correspond to a region at which P-type transistors are to be formed. Accordingly, the first region 101 may correspond to an N-type region and the second region 103 may correspond to a P-type region.

FIG. 1F is a cross-sectional Y-view of the integrated circuit 100, in accordance with some embodiments. The view of FIG. 1F can correspond to the view of FIG. 1E, except that the first region 101 and the second region 103 are both illustrated. In particular, a stack of channels 107 is illustrated in each region 101/103. The stack of channels 107 in the region 101 will eventually correspond to channels of an N-type transistor. The stack of channels 107 in the region 103 will eventually correspond to channels of a P-type transistor.

In FIG. 1F, a hard mask layer 134 has been conformally deposited in the region 101 and in the region 103, in accordance with some embodiments. In particular, the hard mask layer 134 is conformally deposited on the high-K gate dielectric layer 130 at the regions 101 and 103. The hard mask layer 134 wraps around the channels 107 and the hard mask nanostructure 111 of the regions 101 and 103.

In some embodiments, the hard mask layer 134 includes aluminum oxide, AlN, TiO, or other suitable hard mask materials. The hard mask layer 134 can be formed by ALD, PVD, CVD, or other suitable deposition processes. The hard mask layer 134 can include other materials or deposition processes without departing from the scope of the present disclosure.

FIG. 1G is a cross-sectional X-view of the integrated circuit 100 at the stage of processing shown in FIG. 1F, in accordance with some embodiments. The view of FIG. 1G may be termed an upper X-view as only an upper portion above the stacks of channels 107 is shown. In particular, the upper X-view illustrates the hard mask nanostructure 111 with the gate spacers 124 above the hard mask nanostructure 111. More particularly, the upper X-view of region 101 is taken along cut lines Xn of the region 101 of FIG. 1F. The upper X-view of region 103 is taken along cut lines Xp of region 103 of FIG. 1F. The view of FIG. 1G illustrates the high-K gate dielectric layer and the hard mask layer present on the inner sidewalls of the gate spacers 124 and on the upper surface of the hard mask nanostructure 111.

Some of the subsequent pairs of Figures may each illustrate a Y-view as shown in FIG. 1F and an upper X-view as shown in FIG. 1G, but not subsequent stages of processing. In these present figures, may be understood that the upper X-views are taken along cut lines similar to cut lines Xn and Xp of FIG. 1F.

FIGS. 1H and 1I are a Y-view and upper X-view of the integrated circuit 100, respectively, in accordance with some embodiments. In FIGS. 1H and 1I, a layer of photo resist 136 has been deposited at the regions 101 and 103. The photoresist 136 fills the gaps between channels 107 and the hard mask nanostructures 111 and between the gate spacers 124. The photoresist layer 136 may correspond to a bottom antireflective coating (BARC) layer.

FIGS. 1J and 1K are a Y-view and upper X-view of the integrated circuit 100, respectively, in accordance with some embodiments. In FIGS. 1J and 1K, the layer of photoresist 136 has been patterned. In one example the layer of photoresist 136 can be patterned by a high-power global etching process that etches in the vertical direction. The photoresist 136 is removed from all locations except those directly below the outer edges of the hard mask layer wrapped around the hard mask nanostructure 111. The result is that the layer of photoresist 136 remains between channels 107 in the regions 101 and 103. The photoresist 136 is removed between gate spacers 124. In some cases, it is possible, that the upper portion of the high-K gate dielectric layer above the hard mask nanostructures 111 may be damaged by the high-power bombardment of the etching process. After the etching process, the lateral sidewalls of the hard mask layer 134 on the hard mask nanostructure 111 are not covered by the layer of photoresist 136. The hard mask layer 134 around the channels 107 remains entirely covers.

FIGS. 1L and 1M are a Y-view and upper X-view of the integrated circuit 100, respectively, in accordance with some embodiments. An etching process has been performed to remove the hard mask layer 134 from all locations that are not covered by the layer of photoresist 136. The result is that the hard mask layer 134 is no longer present on the side surfaces and top surfaces of the high-K gate dielectric layer 130 around the hard mask nanostructures 111 or between the gate spacers 124. The hard mask layer 134 remains on a bottom portion of the high-K gate dielectric layer 130 on the hard mask nanostructures 111. The etching process may also partially etch the exposed portions of the high-K gate dielectric layer 130 on the hard mask nanostructures 111.

FIGS. 1N and 1O are a Y-view and upper X-view of the integrated circuit 100, respectively, in accordance with some embodiments. In FIGS. 1N and 1O, a hard mask layer 138 has been deposited on the remaining portions of the hard mask layer 134 and on exposed portions of the high-K gate dielectric layer 130. In some embodiments, the hard mask layer 138 is a same material as the hard mask layer 134. In FIGS. 1N and 1O, the hard mask layer 134 may be considered merged with the hard mask layer 138. Accordingly, the hard mask layer 138 is thick enough between adjacent channels 107 and between the top channels 107 and the hard mask nanostructures 111, that there is no remaining gap between adjacent channels 107 and between the top channels 107 and the hard mask nanostructures 111. The hard mask layer 138 can have the materials and deposition processes described in relation to the hard mask layer 134.

FIGS. 1P and 1Q are a Y-view and upper X-view of the integrated circuit 100, respectively, in accordance with some embodiments. In FIGS. 1P and 1Q, a photoresist layer 140 has been deposited and patterned. Initially, the layer of photoresist layer 140 covered both regions 101 and 103, however, after patterning, the layer of photoresist layer 140 covers only the region 101.

In FIGS. 1P and 1Q, and etching process has been performed after patterning of the layer of photoresist layer 140. The etching process entirely removes the hard mask layer 138 (including the remaining portions of the hard mask layer 134) from the region 103. The hard mask layer 138 remains in the region 101 because hard mask layer 138 is covered by the layer of photoresist layer 140 in the region 101. The high-K gate dielectric layer 130 on top of the hard mask nanostructure 111 of the region 103 may be damaged by the patterning process of the layer of photoresist layer 140.

FIGS. 1R and 1S are a Y-view and upper X-view of the integrated circuit 100, respectively, in accordance with some embodiments. In FIGS. 1R and 1S, the layer of photoresist layer 140 has been removed from the region 101 via an ashing process or other type of removal process. After removal of the layer of photoresist layer 140, an isotropic etching process is performed to remove the hard mask layer 138 from side portions of the high-K gate dielectric layer 130 on the sides of the channels 107. The hard mask layer 138 remains directly between the channels 107 and between the top channel 107 and the hard mask nanostructure 111 at the region 101. The etching process can include a timed etch, a wet etch, or other types of etching processes.

FIGS. 1T and 1U are a Y-view and upper X-view of the integrated circuit 100, respectively, in accordance with some embodiments. In FIGS. 1T and 1U, a gate metal 142 has been deposited. The gate metal 142 is deposited on exposed surfaces of the high-K gate dielectric layer 130 at the regions 101 and 103, and on exposed portions of the hard mask layer 138 of the region 101. More particularly, the gate metal 142 is deposited on sidewalls of the remaining hard mask layer 138. At the region 103, the gate metal 142 is formed rapid entirely around the channels 107 and the hard mask nanostructure 111 such that gaps remain between the channels 107 and between the top channel 107 and the hard mask nanostructure 111 at the region 103.

In some embodiments, the gate metal 142 includes TiN, WN, WCN, TaN, Ru, Co, W, or other suitable materials. The gate metal 142 can be deposited by ALD PVD, CVD, or other suitable deposition processes.

FIGS. 1V and 1W are a Y-view and upper X-view of the integrated circuit 100, respectively, in accordance with some embodiments. In FIGS. 1V and 1W, a layer of photoresist 144 has been deposited. The layer photoresist 144 is deposited on exposed surfaces of the gate metal 142. At the region 103, the layer of photoresist 144 is positioned in gaps between the channels 107 and the hard mask nanostructure 111.

FIGS. 1X and 1Y are a Y-view and upper X-view of the integrated circuit 100, respectively, in accordance with some embodiments. In FIGS. 1X and 1Y, a high-power etching process has been performed to remove the layer of photoresist layer 144 at all locations except between the channels 107 and between the top channel 107 and the hard mask nanostructure 111. The etching process may result in damage to the high-K gate dielectric layer 130 above the hard mask nanostructure 111.

FIGS. 1Z and 2A are a Y-view and upper X-view of the integrated circuit 100, respectively, in accordance with some embodiments. In FIGS. 1Z and 2A, an etching process has been performed to remove the gate metal 142 entirely from the region 101 and at portions of the region 103 at which the gate metal 142 was not covered by the layer of photoresist 144. More particularly, at the region 103, the gate metal 142 is removed from all side surfaces of the channels 107 and the hard mask nanostructure 111. The gate metal 142 remains directly between the channels 107 and directly between the top channel 107 and the hard mask nanostructure 111 at the region 103.

After the etching process to remove portions of the gate metal 142, the layer of photoresist 144 is removed entirely from the region 103. The remaining portions of the gate metal 142 may correspond to a work function gate metal for the P-type transistors that will be formed at the region 103.

FIGS. 2B and 2C are a Y-view and upper X-view of the integrated circuit 100, respectively, in accordance with some embodiments. In FIGS. 2B and 2C, a gate metal 146 has been deposited. The gate metal 146 is deposited on all exposed surfaces at the regions 101 and 103. The result is that the gate metal 146 is positioned on sidewalls of the high-K gate dielectric layer 130 and on sidewalls of the hard mask layer 138 at the region 101. At the region 103, the gate metal 146 is deposited on exposed portions of the high-K gate dielectric layer 130 and the remaining portions of the gate metal 142. The result is that at the region 103, the gate metal 146 fills the spaces between adjacent channels 107 and between a top channel 107 and the hard mask nanostructure 111.

In some embodiments, the gate metal 146 includes TiN, WN, WCN, TaN, Ru, Co, W, or other suitable materials. The gate metal 146 can be deposited by ALD, PVD, CVD, or other suitable deposition processes. The gate metal 146 may be different than the gate metal 142.

FIGS. 2D and 2E are a Y-view and upper X-view of the integrated circuit 100, respectively, in accordance with some embodiments. In FIGS. 2D and 2E, a layer of photoresist 148 has been deposited and patterned. The layer of photoresist 148 remains at the region 103 and is absent from the region 101.

FIGS. 2F and 2G are a Y-view and upper X-view of the integrated circuit 100, respectively, in accordance with some embodiments. In FIGS. 2F and 2G, an etching process has been performed to remove the gate metal 146 from the region 101. Because the layer of photoresist 148 is present at the region 103, the gate metal 146 is not removed at the region 103.

FIGS. 2H and 2I are a Y-view and upper X-view of the integrated circuit 100, respectively, in accordance with some embodiments. In FIGS. 2H and 2I, the layer of photoresist 148 has been removed from the region 103. A gate metal 150 has been conformally deposited at the regions 101 and 103. At the region 101, the gate metal 150 is in direct contact with the high-K gate dielectric layer 130 and wraps around each of the channels 107 and the hard mask nanostructure 111. Accordingly, the gate metal 150 is positioned between adjacent channels 107 and between a top channel 107 and the hard mask nanostructure 111 at the region 101. At the region 103, the gate metal 150 is positioned in contact with the gate metal 146.

At the region 103, the gate metal 150 does not extend between adjacent channels 107 and between the top channel 107 and the hard mask nanostructure 111. This is because the gate metal 146 fills the gaps between adjacent channels 107 and between the hard mask nanostructure 111 and the top channel 107 at the region 103.

In some embodiments, the gate metal 150 is a work function metal for the N-type transistors at the region 101. The gate metal 150 can include TiN, TaN, WN, WCN, Ru, Co, W, or other suitable materials. The gate metal 150 can be deposited via ALD, PVD, CVD, or other suitable deposition processes.

In FIGS. 2H and 2I, a gate metal 152 has been conformally deposited at the regions 101 and 103. At the region 101, the gate metal 152 is in direct contact with the gate metal 150 and wraps around each of the channels 107 and the hard mask nanostructure 111. Accordingly, the gate metal 152 is positioned between adjacent channels 107 and between a top channel 107 and the hard mask nanostructure 111 at the region 101. At the region 103, the gate metal 152 is positioned in contact with the gate metal 150.

At the region 103, the gate metal 152 does not extend between adjacent channels 107 and between the top channel 107 and the hard mask nanostructure 111. This is because the gate metal 146 fills the gaps between adjacent channels 107 and between the hard mask nanostructure 111 and the top channel 107 at the region 103.

In some embodiments, the gate metal 152 includes a glue layer. The gate metal 152 can include Ti, Ag, Al, TiAl, TiAlN, TiAlC, TaAl, TaC, TaCN, TaSiN, TaAlC, Mn, Zr, or other suitable materials. The gate metal 152 can be deposited via ALD, PVD, CVD, or other suitable deposition processes. The gate metal 152 may entirely fill all remaining gaps around the channels 107 at the regions 101 and 103. Alternatively, an additional gate metal 154 may be deposited to fill any remaining gaps around the channels 107 and between the gate spacers 124. The gate metal 154 is apparent in FIG. 2I, but is not shown in FIG. 2H. If the gate metal 152 fills all remaining gaps, then the gate metal 154 will not be present. The gate metal 154 can include W or other suitable materials. The gate metal 154 can be deposited by ALD, PVD, CVD, or other suitable deposition processes.

After deposition of the gate metals 152 and 154, a CMP process may be performed to remove any excess gate metal materials on top surfaces of the interlevel dielectric layer 126.

In the stage of processing shown in FIGS. 2H and 2I, processing of transistors at the regions 101 and 103 may be substantially complete. In particular, a transistor 156a is formed at the region 101 and the transistor 156b is formed at the region 103. In some embodiments, the transistor 156a is an N-type transistor and a transistor 156b is a P-type transistor.

FIG. 2J is an X-view of a transistor 156 corresponding to the view shown in FIG. 1D, but at the stage of processing shown in FIGS. 2H and 2I, in accordance with some embodiments. The transistor 156 of FIG. 2J can represent the transistor 156a or the transistor 156b. The high-K gate dielectric layer 130 is present around the channels 107 and above the hard mask nanostructure 111. A gate electrode 160 wraps around the channels 107 and the hard mask nanostructure 111 and is present between the gate spacers 124. The gate electrode 160 is shown as a single layer but represents all of the gate metals that may be present at the region 101 or 103. For a P-type transistor 156b, the gate electrode 160 may include the gate metals 142, 146, 150, 152, and 154. For an N-type transistor 156a, the gate electrode 160 may include the gate metals 150, 152, and 154. The gate metals 142, 146, 150, 152, and 154 may also be termed gate metal layers.

FIG. 2J illustrates how the inner spacers 120 electrically isolate the gate electrode 160 from the source/drain regions 118. The gate metal 160 may be termed a gate electrode. Though not shown in FIG. 2J, source/drain contacts may be formed in the interlevel dielectric layer 126 to provide electrical contact to the source/drain regions 118. The transistor 156 operates by applying a gate voltage to the gate electrode 160, and source/drain voltages to the source/drain regions 118. When the transistor 156 is turned on, the current flows through each of the channels 107 between the source/drain regions 118. When the transistor 156 is turned off, substantially zero current flows through the channels 107. FIG. 2J also illustrates how the hard mask nanostructure 111 also extends between the source/drain regions 118 and has lateral sidewalls in direct contact with the source/drain regions 118. A transistor 156 can have other configurations without departing from the scope of the present disclosure

FIG. 2K is a Y-view of the integrated circuit 100 at the stage of processing shown in FIG. 2H, in accordance with some embodiments. FIG. 2K illustrates that the high-K gate dielectric layer 130 has a varying thickness around the hard mask nanostructure 111 at the regions 101 and 103. In particular, the high-K gate dielectric layer 130 has a first thickness D1 on a top surface of the hard mask nanostructure 111 and a second thickness D2 on a bottom surface of the hard mask nanostructure 111. The thickness D1 is less than the thickness D2. This may result from the various etching processes that remove the layer of photoresist layers and other layers throughout processing at the regions 101 and 103. In some embodiments, the thickness D1 is between 0 nm and 0.5 nm. In some embodiments, the thickness D2 is between 0.5 nm and 2 nm. Other values for D1 and D2 may be utilized without departing from the scope of the present disclosure. The thickness of the high-K gate dielectric layer 130 around the channels 107 is substantially equal to D2 and is uniform around the channels 107.

Because the hard mask nanostructures 111 do not carry the current and did not affect the threshold voltage of the transistors 156, the difference in thicknesses of the gate dielectric layer 130 around the hard mask nanostructures 111 does not adversely affect the function of the transistors 156. The thickness of the high-K gate dielectric layer 130 around the channels 107 of both of the transistors 156 is substantially uniform and the high-K gate dielectric layer 130 around the channels 107 is substantially undamaged. The result is that the transistors 156a and 156b have very good electrical function.

The transistor 156a includes a gate electrode 160a including the gate metals 150 and 152. The transistor 156b includes a gate electrode 160b including the gate metals 142, 146, 150 and 152.

As described previously, the hard mask nanostructures 111 have a width dimension in the Y direction that is greater than a width dimension of the channels 107. Accordingly, a lateral end of the hard mask nanostructures 111 overhang a lateral end of the channels 107 by a dimension D3 in the Y direction. In some embodiments, the dimension D3 is between 0 nm and 4 nm, though other values can be utilized without departing from the scope of the present disclosure.

The hard mask nanostructures 111 have a thickness dimension D4 in the Z direction. In some embodiments, the dimension D4 is between 1 nm and 10 nm, though other values can be utilized without departing from the scope of the present disclosure.

Each transistor 156 has a dimension D5 separating the gate spacers 124 in the X direction (see FIG. 2I). In some embodiments, the dimension D5 is between 8 nm and 15 nm, though other values can be utilized without departing from the scope of the present disclosure. In some embodiments, adjacent fins 112 are separated from each other by distance between 20 nm and 60 nm, though other distances can be utilized without departing from the scope of the present disclosure.

Adjacent channels 107 are separated from each other in the Z direction by a dimension D6. In some embodiments, the dimension D6 is between 5.5 nm and 15 nm, though other values can be utilized without departing from the scope of the present disclosure. The presence of the hard mask nanostructure 111 allows for a larger dimension D5. This in turn allows for flexibility in the dimension D6. The dimension D6 may be smaller, equal to, or larger than the dimension D5. In some possible solutions, scaling is limited by a proposition that a gate width should be larger than a vertical distance between adjacent channels of the transistor. However, embodiments of the present disclosure overcome the drawbacks of other possible solutions by providing a hard mask nanostructure that enables flexibility in the design of the dimensions D5 in D6. In particular, the dimension D6 can be less than, greater than, or equal to the dimension D5. This can permit aggressive scaling of critical poly-gate pitch and cell height.

At the boundary between regions 101 and 103, there is a mismatch in height between a top surface of the gate metal 150 of the region 101 and the region 103. In particular, the top surface of the gate metal 150 at the region 103 is higher than the top surface of the gate metal 150 at the region 101 by a dimension D7. The dimension D7 may be between 0 nm and 5 nm.

The gate metal 146 has a thickness dimension D8 in the Y direction on lateral surfaces of the hard mask nanostructure 111 and the channels 107 at the region 103. The gate metal 146 (combined with the gate metal 142) between adjacent channels 107 has a thickness dimension D9. D9 is greater than D8. In some embodiments, D8 is between 0.5 nm and 5 nm and D9 is between 3 nm and 10 nm, though other values can be utilized without departing from the scope of the present disclosure.

In some embodiments, the hard mask nanostructures 111 have a width dimension D10 in the Y direction between 9 nm and 100 nm, though other values can be utilized without parting from the scope of the present disclosure. In some embodiments, the channels 107 have a width dimension D11 in the Y direction between 6 nm and 100 nm, though other values can be utilized without departing from the scope of the present disclosure. D11 is less than D10. In some embodiments, the channels 107 have a height dimension D12 in the Z direction between 3 nm and 10 nm, though other values can be utilized without departing from the scope of the present disclosure. D12 is less than D4.

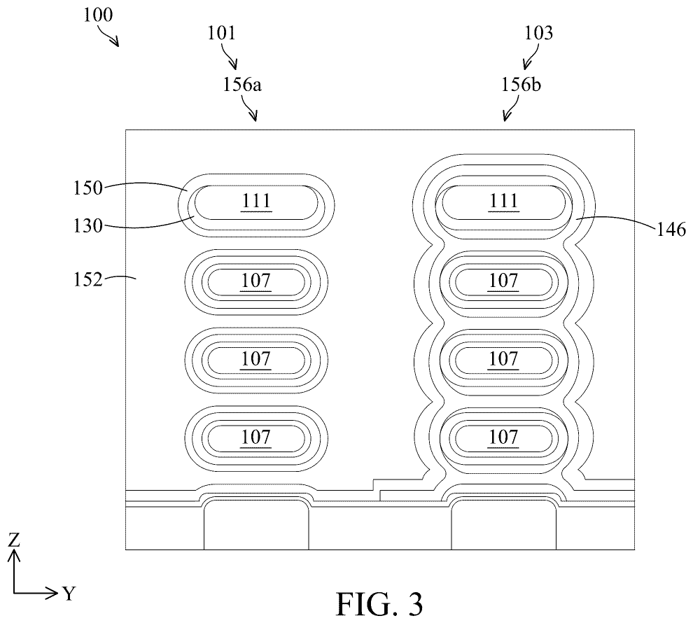

FIG. 3 is a cross-sectional view of an integrated circuit 100, in accordance with some embodiments. The integrated circuit 100 of FIG. 3 is substantially the same as stage of processing as shown in FIG. 2K. However, in the example of FIG. 3, the high-K gate dielectric layer 130 has been entirely removed from the top surface of the hard mask nanostructures 111 due to the various photoresist removal processes described previously. The result is that the gate metal 150 is in direct contact with a top surface of the hard mask nanostructure 111 at the transistor 156a. The gate metal 146 is in direct contact with the top surface of the hard mask nanostructure 111 at the transistor 156b. No such problems are present at the top surfaces of the channels 107. Accordingly, the hard mask nanostructures 111 protect the channels 107 and the overall function of the transistors 156.

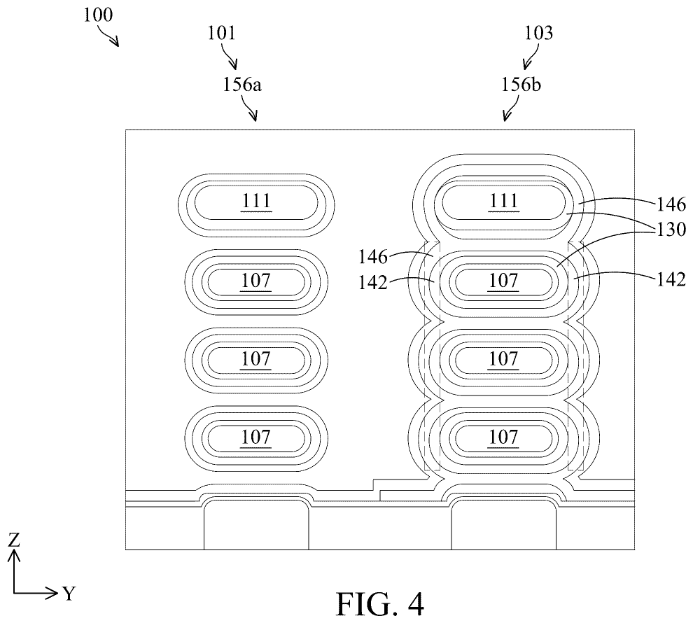

FIG. 4 is a cross-sectional view of an integrated circuit 100, in accordance with some embodiments. The integrated circuit 100 of FIG. 4 is substantially the same as stage of processing as shown in FIG. 2K. However, in the example of FIG. 4, the gate metal 142 remains present on lateral surfaces of the high-K gate dielectric layer 130 at the transistor 156b. This may result from the layer of photoresist layer 144 at FIG. 1X remaining on the side surfaces of the gate metal 142 due to the overlapping nature of the hard mask nanostructure 111. Accordingly, the gate metal 142 may not be entirely removed from sides of the channels 107 of the region 103 during the etching process described in relation to FIG. 1Z. The result is the structure shown in FIG. 4.

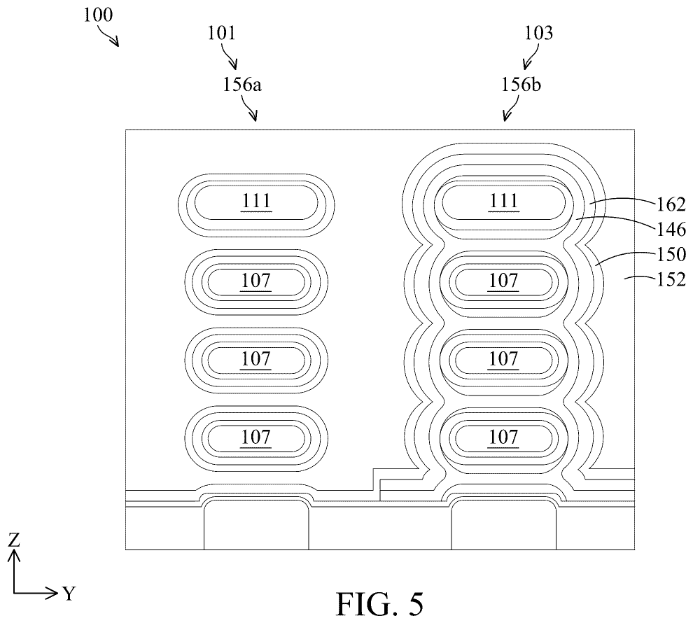

FIG. 5 is a cross-sectional view of an integrated circuit 100, in accordance with some embodiments. The integrated circuit 100 of FIG. 5 is substantially the same as stage of processing as shown in FIG. 2K. However, in the example of FIG. 5, a semiconductor layer 162 has been formed on the gate metal 146 at the region 103. In some embodiments, the semiconductor layer 162 includes silicon, though other semiconductor materials can be utilized without departing from the scope of the present disclosure. The semiconductor layer 162 can be formed through ALD, PVD, CVD, or epitaxy, though other processes can be utilized without departing from the scope of the present disclosure. One benefit of the presence of the semiconductor layer 162 is that materials (for example, aluminum) from the gate metal 150 cannot diffuse into the gate metal 146 at the transistor 156b. This can help maintain proper electrical function of the transistor 156b.

The semiconductor layer 162 can be formed in the following manner. After deposition of the gate metal 146, and prior to forming the layer of photoresist layer 148, the semiconductor layer 162 can be deposited at the regions 101 and 103. Subsequently, the layer of photoresist layer 148 may be formed and patterned as described in relation to FIGS. 2D and 2E so that the semiconductor layer 162 is exposed at the region 101 but not the region 103. An etching process may then be performed to remove the semiconductor layer 162 at the region 101. The etching process described in relation to FIGS. 2F and 2G is then performed to remove the gate metal 146 from the region 101. Other processes can be utilized to form the semiconductor layer 162 without departing from the scope of the present disclosure.

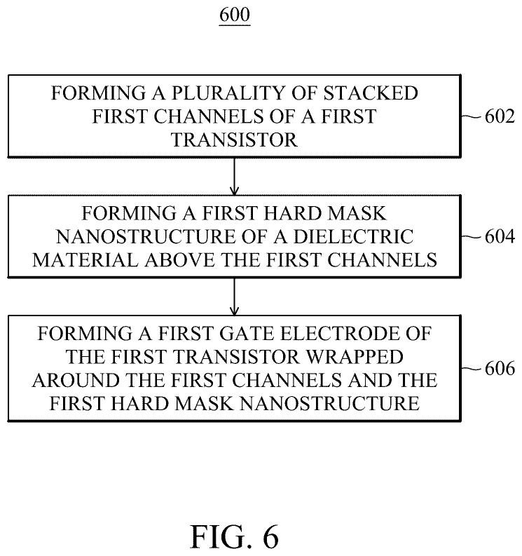

FIG. 6 is a flow diagram of a method 600 for forming an integrated circuit, in accordance with some embodiments. The method 600 can utilize the structures, processes, and systems described in relation to FIGS. 1A-5. At 602, the method 600 includes forming a plurality of stacked first channels of a first transistor. One example of a first transistor is the transistor 156 of FIG. 2J. One example of stacked first channels are the channels 107 of FIG. 2J. At 604, the method includes forming a first hard mask nanostructure of a dielectric material above the first channels. One example of first hard mask nanostructure is the hard mask nanostructure of FIG. 2J. At 606, the method 600 includes forming a first gate electrode of the first transistor wrapped around the first channels and the first hard mask nanostructure. One example of a first gate electrode is the gate electrode 160 of FIG. 2J.

Embodiments of the disclosure provide nanostructure transistors that each include a plurality of stacked channels. A hard mask nanostructure is positioned above the highest channel of each transistor. The gate metals of the transistors wrap around the channels and the hard mask nanostructures. The presence of the hard mask nanostructure helps prevent loss of the high-K gate dielectric from a top surface of the highest channel of each transistor. Furthermore, the presence of the hard mask nanostructure helps reduce the constraints of gate width spacing. The result is that further scaling of critical poly-gate pitch and cell height can be achieved. The result is that scaling of transistors can be improved while electrical characteristics of transistors are protected and maintained. This results in improved wafer yields and better functioning electronic devices.

In one embodiment, a device includes a transistor. The transistor includes a first source/drain region, a second source/drain region, and a plurality of stacked channels each extending in a first lateral direction between the first source/drain region and the second source/drain region. The transistor includes a hard mask nanostructure of dielectric material directly above the channels and extending in the first lateral direction between the first source/drain region and the second source/drain region and a gate electrode wrapped around each of the channels and the hard mask nanostructure.

In one embodiment, a device includes a first transistor including a plurality of stacked first channels and a first hard mask nanostructure above the first channels. The device includes a second transistor including a plurality of stacked second channels and a second hard mask nanostructure above the second channels. The device includes a high-K gate dielectric layer wrapped around the first channels, the first hard mask nanostructure, the second channels, and the second hard mask nanostructure, a first gate metal in contact with the high-K gate dielectric layer at the first transistor and wrapped around the first channels and the first hard mask nanostructure, and a second gate metal in contact with the high-K gate dielectric layer at the second transistor and wrapped around the second channels and the second hard mask nanostructure.

In one embodiment, a method includes forming a plurality of stacked first channels of a first transistor, forming a first hard mask nanostructure of a dielectric material above the first channels, and forming a first gate electrode of the first transistor wrapped around the first channels and the first hard mask nanostructure.

In one embodiment, a device includes a transistor. The transistor includes a plurality of stacked channels, a source/drain region in contact with each of the stacked channels, and a gate metal wrapped around the stacked channels and including an upper portion above a highest channel of the stacked channels. The transistor includes an inner spacer including a gap above the highest channel and laterally between the upper portion of the gate metal and the source/drain region and a dielectric helmet structure above the gap and in contact with the source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a transistor including:
a first source/drain region;
a second source/drain region;
a plurality of stacked channels each extending in a first lateral direction between the first source/drain region and the second source/drain region;
a hard mask nanostructure of dielectric material directly above the channels and having a same width in the first lateral direction as the channels;
gate spacer layers on the hard mask nanostructure; and
a gate electrode between the gate spacer layers and wrapped around each of the channels and the hard mask nanostructure.

2. The device of claim 1, comprising a high-K gate dielectric layer between the channels and the gate electrode, between the hard mask nanostructure and the gate electrode, and wrapped around each of the channels and the hard mask nanostructure, the high-K gate dielectric layer having first thickness on a top surface of the hard mask nanostructure and a second thickness less than the first thickness on a bottom surface of the hard mask nanostructure.

3. The device of claim 2, wherein the high-K gate dielectric layer has a uniform thickness on the channels equal to the second thickness.

4. The device of claim 1, wherein the hard mask nanostructure has a same length as the channels in the first lateral direction, wherein the hard mask layer has a width dimension in a second lateral direction that is greater than a width of the channels in the second lateral direction.

5. The device of claim 1, wherein the gate electrode has a width in the first lateral direction above the hard mask nanostructure that is less than or equal to a vertical distance between adjacent channels.

6. The device of claim 1, wherein the transistor includes a high-K gate dielectric layer wrapped around the channels, wherein the gate electrode includes a gate metal on the high-K gate dielectric and having a first thickness on sides of the channels and a second thickness greater than the first thickness between adjacent channels.

7. The device of claim 1, wherein the transistor includes a high-K gate dielectric layer wrapped around the channels, wherein the gate electrode includes:
a first gate metal in direct contact with the high-K gate dielectric at bottom surfaces of the channels; and
a second gate metal in direct contact with the high-K gate dielectric at sides of the channels and separated from the high-K gate dielectric at bottom surfaces of the channels.

8. The device of claim 7, wherein the gate electrode includes a third gate metal on the second gate metal, wherein the third gate metal is not positioned between adjacent channels.

9. The device of claim 1, wherein the transistor includes a high-K gate dielectric layer wrapped around the channels and on a bottom surface of the hard mask nanostructure, wherein the gate electrode is separated from the bottom surface of the hard mask by the high-K gate dielectric layer, wherein the gate electrode is in direct contact with a top surface of the hard mask nanostructure.

10. The device of claim 1, wherein the transistor includes a high-K gate dielectric layer wrapped around the channels, wherein the gate electrode includes:
a first gate metal on the high-K gate dielectric;
a semiconductor layer on the first gate metal; and
a second gate metal on the semiconductor layer.

11. The device of claim 1, wherein the gate electrode includes a third gate metal on the second gate metal.

12. The device of claim 11, comprising first gate spacer and a second gate spacer on the hard mask nanostructure, the gate electrode being positioned between the first and second gate spacers above the hard mask nanostructure.

13. A method, comprising:
forming a semiconductor fin including a hard mask layer on the semiconductor fin;
defining a plurality of stacked channels from the semiconductor fin and defining a hardmask nanostructure over the channels from the hard mask layer by forming a first trench and a second trench in the semiconductor fin;
forming a first source/drain region in the first trench and a second source/drain region in the second trench, the channels and the hard mask nanostructure extending in a first lateral direction between the first source/drain region and the second source/drain region;
forming a high-K gate dielectric layer wrapped around the channels and the first hard mask nanostructure; and
forming a gate metal wrapped around the hard mask nanostructure and the channels.

14. The method of claim 13, further comprising:
forming first and second gate spacer layers over the hard mask layer; and
forming the first and second trenches using the first and second gate spacer layers as a mask.

15. The method of claim 14, further comprising forming the gate metal between the first and second gate spacer layers.

16. The method of claim 13, further comprising forming an inner spacer in contact with a bottom surface of the hard mask nanostructure.

17. A method, comprising:
forming a hard mask nanostructure of dielectric material below a first gate spacer layer and a second gate spacer layer;
forming a first channel and second channel of a transistor below the hard mask nanostructure;
forming a first source/drain region and a second source/drain region of the transistor, the first and second channels extending in a first lateral direction between the first and second source/drain regions; and
forming a gate metal between the first and second gate spacer layers and wrapped around the first and second channels and the hard mask nanostructure.

18. The method of claim 17, further comprising forming a first inner spacer between the first and second channels and forming a second inner spacer between the second channel and the hard mask nanostructure.

19. The method of claim 18, further comprising:
removing a first sacrificial semiconductor nanostructure from between the first and second channels and removing a second sacrificial nanostructure from the second channel and the hard mask nanostructure prior to forming the gate metal; and
forming the gate electrode in place of the sacrificial nanostructures.

20. The method of claim 18, wherein the hard mask nanostructure extends in the first lateral direction between the first and second source/drain regions.
